(19) United States
(12) Patent Application Publication
(10) Pub. No.: US 2022/0397606 A1
(43) Pub. Date: Dec. 15, 2022

(54) METHOD FOR CONTROLLING DROP TEST EQUIPMENT

(71) Applicant: Konepaja-Heinä Oy, Halikko (FI)

(72) Inventor: Ilkka HEINÄ, Halikko (FI)

(73) Assignee: Konepaja-Heinä Oy, Halikko (FI)

(21) Appl. No.: 17/833,449

(22) Filed: Jun. 6, 2022

(30) Foreign Application Priority Data
Jun. 10, 2021 (FI) 20215675

(51) Int. Cl. G01R 31/319; G01R 31/28; G01R 31/317

(52) U.S. Cl. CPC G01R 31/31905; G01R 31/31912; G01R 31/2872; G01R 31/31719

(57) ABSTRACT

Controlling of drop test equipment. A predefined test script is obtained over a machine-machine interface. The test script comprises plurality of test settings for drop testing of a device-under-test, DUT. The drop test equipment is controlled to perform drop testing of the DUT according to the test settings of the test script. Test results are collected and provided to a test report.

### TECHNICAL FIELD

The present application generally relates to drop testers and to controlling drop testers.

### BACKGROUND

This section illustrates useful background information without admission of any technique described herein representative of the state of the art.

A drop tester is a device intended for testing and verifying mechanical resistance of products. An example drop tester has a device-under-test (DUT) holder, which allows for holding the DUT in well-defined orientations, then allows a sled/bracket with holder and the DUT to free-fall from an adjustable height, releasing the DUT just before impact. The DUT then hits the drop base material placed at the bottom, e.g., a concrete slab, with well-defined acceleration and orientation, allowing for good repeatability. E.g. consumer electronics, toys, medical devices etc. are often tested with such drop testers.

### SUMMARY

The appended claims define the scope of protection. Any examples and technical descriptions of apparatuses, products and/or methods in the description and/or drawings not covered by the claims are presented not as embodiments of present disclosure but as background art or examples useful for understanding the present disclosure.

According to a first example aspect there is provided a computer implemented method for controlling drop test equipment. The method comprises
obtaining, over a machine-machine interface, a predefined test script comprising a plurality of test settings for drop testing of a device-under-test, DUT;
controlling the drop test equipment to perform drop testing of the DUT according to the test settings defined in the test script;
collecting test results for the plurality of test settings; and
providing the collected test results to a test report.

According to a second example aspect there is provided a computer implemented method for controlling drop testing. The method comprises
providing, in a data handling environment, a human-machine interface allowing a supervisor to define a test script comprising a plurality of test settings for drop testing of a device-under-test, DUT;
transferring the test script, over a machine-machine interface, from the data handling environment to a control unit of a drop test equipment to control the drop test equipment to perform drop testing of the DUT according to the test settings defined in the test script; and
collecting, over the machine-machine interface, test results for the plurality of test settings.

According to a third example aspect, there is provided an apparatus, such as a control unit of a drop test equipment, comprising
a machine-machine interface; and
processing intelligence configured to control drop test equipment;
wherein the processing intelligence is configured
   to obtain, over the machine-machine interface, a predefined test script comprising a plurality of test settings for drop testing of a device-under-test, DUT;
   to control the drop test equipment to perform drop testing of the DUT according to the test settings defined in the test script;
   to collect test results for the plurality of test settings; and
   to provide the collected test results to a test report.

In some embodiments, the apparatus of the third example aspect further comprises a human-machine interface and the processing intelligence is configured to implement controlling the drop test equipment and/or collecting the test results through the human-machine interface.

According to a fourth example aspect there is provided an apparatus, such as a data handling environment, comprising
a human-machine interface;
a machine-machine interface; and
processing intelligence configured to control drop testing;
wherein the processing intelligence is configured
   to allow a supervisor to define, through the human-machine interface, a test script comprising a plurality of test settings for drop testing of a device-under-test, DUT;
   to transfer the test script, over the machine-machine interface, to a control unit of a drop test equipment to control the drop test equipment to perform drop testing of the DUT according to the test settings defined in the test script; and
   to collect, over the machine-machine interface, test results for the plurality of test settings.

According to a fifth example aspect, there is provided an apparatus comprising a machine-machine interface, a processor and a memory including computer program code; the memory and the computer program code configured to, with the processor, cause the apparatus to perform the method of the first or second aspect or any related embodiment.

According to a sixth example aspect, there is provided a computer program comprising computer executable program code which when executed by a processor causes an apparatus to perform the method of the first or second aspect or any related embodiment.

According to a seventh example aspect there is provided a computer program product comprising a non-transitory computer readable medium having the computer program of the fifth example aspect stored thereon.

According to an eighth example aspect there is provided an apparatus comprising means for performing the method of the first or the second aspect or any related embodiment.

According to a ninth example aspect there is provided a system comprising the apparatuses of the third and fourth aspects. The system may further comprise the drop test equipment.

In some embodiments, one or more of the example aspects further comprises monitoring settings of the drop test equipment before or during drop testing of the DUT; and providing feedback if the settings of the drop test equipment do not conform with the test settings of the respective test script.

In some embodiments of one or more of the example aspects, the test settings define one or more of the following: number of drop repetitions, position of the DUT, orientation of the DUT, velocity of the DUT, drop height, temperature, humidity, drop base material.

In some embodiments of one or more of the example aspects, controlling the drop test equipment to perform the drop testing comprises interacting with a human-machine interface to guide the operator of the drop test equipment to perform the drop testing.

In some embodiments of one or more of the example aspects, controlling the drop test equipment to perform the drop testing comprises automatically configuring parameters of the drop test equipment according to test settings of the test script.

In some embodiments of one or more of the example aspects, collecting the test results comprises interacting with a human-machine interface to receive test results from the operator of the drop test equipment.

In some embodiments of one or more of the example aspects, collecting the test results comprises automatically detecting test results.

In some embodiments of the one or more of the example aspects, collecting the test results comprises receiving images of the DUT.

In some embodiments of one or more of the example aspects, test statistics are collected during drop testing of the DUT in addition to collecting the test results.

In some embodiments of one or more of the example aspects, collecting the test results further comprises collecting test statistics during drop testing of the DUT, wherein the test statistics include one or more of the following: total test time, time spent on different phases of the drop testing, number of drop repetitions, position of the DUT, orientation of the DUT, velocity of the DUT, drop height, temperature, humidity.

In some embodiments, one or more of the example aspects further comprises compiling the test report based on the collected test results.

In some embodiments of one or more of the example aspects, providing the collected test results to the test report comprises submitting the collected test results over the machine-machine interface to a predefined destination, such as a predefined network address.

In some embodiments of one or more of the example aspects, at least one test script is allowed to be transferred from the data handling environment to control units of a plurality of different drop test equipment of different drop test sites.

In some embodiments of one or more of the example aspects, the test scripts are used for calibration of the drop test equipment.

In some embodiments of one or more of the example aspects, position of the DUT or position of a mounting head in which the DUT is mounted is obtained, and the obtained position is compared to the test settings.

In some embodiments of one or more of the example aspects, data transfer through the machine-machine interface is secured with an encryption protocol.

In some embodiments of one or more of the example aspects, the test results comprise numerical values, written statements and images of the DUT.

Any foregoing memory medium may comprise a digital data storage such as a data disc or diskette, optical storage, magnetic storage, holographic storage, opto-magnetic storage, phase-change memory, resistive random access memory, magnetic random access memory, solid-electrolyte memory, ferroelectric random access memory, organic memory or polymer memory. The memory medium may be formed into a device without other substantial functions than storing memory or it may be formed as part of a device with other functions, including but not limited to a memory of a computer, a chip set, and a sub assembly of an electronic device.

Different non-binding example aspects and embodiments have been illustrated in the foregoing. The embodiments in the foregoing are used merely to explain selected aspects or steps that may be utilized in different implementations. Some embodiments may be presented only with reference to certain example aspects. It should be appreciated that corresponding embodiments may apply to other example aspects as well.

### BRIEF DESCRIPTION OF THE FIGURES

Some example embodiments will be described with reference to the accompanying figures, in which:

FIG. 1 schematically shows an example system according to an example embodiment;

FIG. 2 shows a block diagram of an apparatus according to an example embodiment;

FIGS. 3 and 4 show flow diagrams illustrating example methods according to certain embodiments.

### DETAILED DESCRIPTION

In the following description, like reference signs denote like elements or steps.

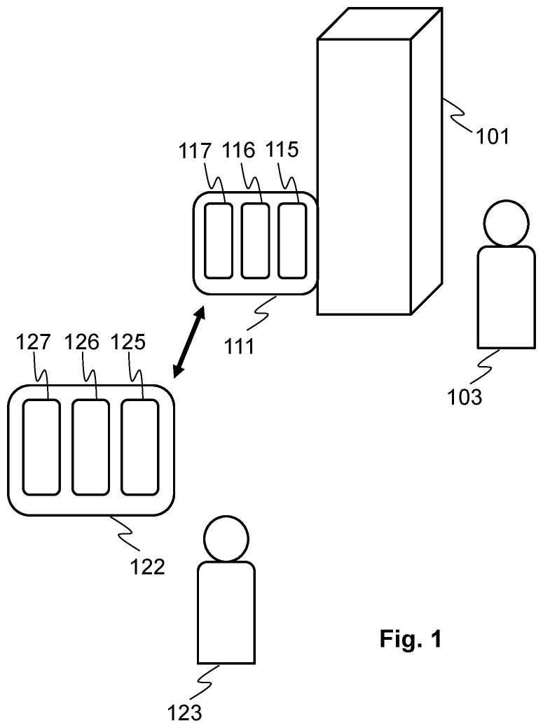

FIG. 1 shows an example system according to an embodiment. The system comprises drop test equipment 101, a control unit 111 of the drop test equipment, operator 103 of the drop test equipment, a data handling environment 121, and a supervisor 123 of at least some of the drop tests performed in the drop test equipment 101.

The drop test equipment 101 is typically a cabinet-like housing, which comprises for example a frame made of aluminum profiles and acrylic or polycarbonate panels for protecting the device mechanics from dust and for protecting the operator 103 from splinters. Within the cabinet, there may be a main vertical column that guides free-fall motion and to which a bracket, which is configured to hold a device-under-test (DUT), is connected. The drop test equipment 101 is typically free-standing and preferably bolted or otherwise fixed to the ground or floor.

The control unit 111 is an electronic device with suitable data processing capabilities. Logical components of the control unit 111 comprise a human-machine interface 115, processing intelligence 116, and a machine-machine interface 117. The human-machine interface 115 is e.g. a touch screen or the like, through which the operator 103 may manually control the drop test equipment 101 or interact with the drop test equipment 101. The processing intelligence 116 is configured to provide at least some parts of automated controlling of drop tests implemented in the drop test equipment 101. The machine-machine interface 117 is configured to enable data transfer to and from the control unit 111 using a suitable communication protocol, such as IP protocol.

The data handling environment 121 may be a general purpose computer or a resource in a cloud service. Logical components of the data handling environment 121 comprise a human-machine interface 125, processing intelligence 126, and a machine-machine interface 127. The human-machine interface 125 allows for example creation of test scripts and/or review of test reports by the supervisor 123. The processing intelligence 126 is configured to provide at least some parts of automated controlling of drop tests performed in the drop test equipment 101. The machine-machine interface 127 is configured to enable data transfer to and from the data handling environment 121 using a suitable communication protocol, such as IP protocol.

The data handling environment 121 and the control unit 111 are configured to interact with each other through the machine-machine interfaces 117 and 127. Data transfer between the machine-machine interfaces 117 and 127 may be secured with a suitable encryption protocol. The interaction may be automatic or semi-automatic. The interaction may be triggered for example by actions performed by the operator 103 or the supervisor 123 or by the processing intelligence 115 of the control unit or the processing intelligence 125 of the data handling environment.

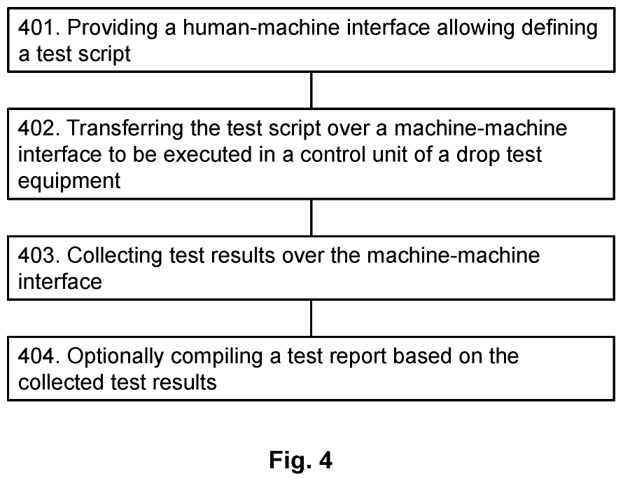

The data handling environment 121 and the control unit 111 are configured to implement at least some example embodiments of present disclosure. It is to be noted that the data handling environment 121 and the control unit 111 are to be treated as logical entities and that the operations thereof may be distributed to more than one physical device. Operation of the data handling environment 121 and the control unit 111 is discussed in more detail below e.g. in connection with FIGS. 3 and 4.

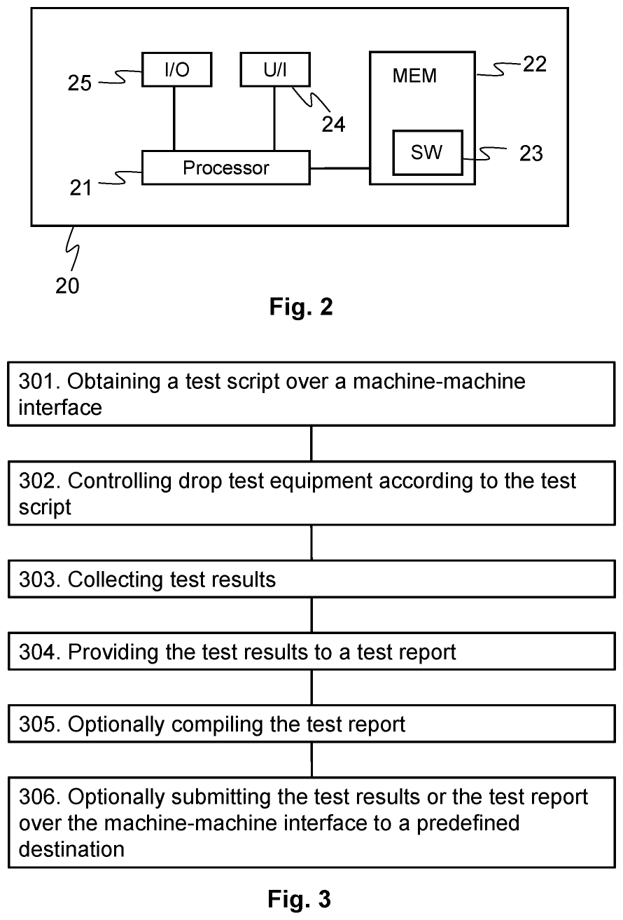

FIG. 2 shows a block diagram of an apparatus 20 according to an embodiment. The apparatus 20 is for example a general-purpose computer or server or some other electronic data processing apparatus. The apparatus 20 can be used for implementing at least some embodiments of present disclosure. That is, with suitable configuration the apparatus 20 is suited for operating for example as the control unit 111 or the data handling environment 121 of foregoing disclosure.

The apparatus 20 comprises a communication interface 25, a processor 21, a user interface 24, and a memory 22. The apparatus 20 further comprises software 23 stored in the memory 22 and operable to be loaded into and executed in the processor 21. The software 23 may comprise one or more software modules and can be in the form of a computer program product.

The processor 21 may comprise a central processing unit (CPU), a microprocessor, a digital signal processor (DSP), a graphics processing unit, or the like. FIG. 2 shows one processor 21, but the apparatus 20 may comprise a plurality of processors.

The user interface 24 is configured for providing interaction with a user of the apparatus. Additionally or alternatively, the user interaction may be implemented through the communication interface 25. The user interface 24 may comprise a circuitry for receiving input from a user of the apparatus 20, e.g., via a keyboard, graphical user interface shown on the display of the apparatus 20, speech recognition circuitry, or an accessory device, such as a headset, and for providing output to the user via, e.g., a graphical user interface or a loudspeaker. The user interface 24 may provide the human-machine interface of various disclosed embodiments.

The memory 22 may comprise for example a non-volatile or a volatile memory, such as a read-only memory (ROM), a programmable read-only memory (PROM), erasable programmable read-only memory (EPROM), a random-access memory (RAM), a flash memory, a data disk, an optical storage, a magnetic storage, a smart card, or the like. The apparatus 20 may comprise a plurality of memories. The memory 22 may serve the sole purpose of storing data, or be constructed as a part of an apparatus 20 serving other purposes, such as processing data.

The communication interface 25 may comprise communication modules that implement data transfer to and from the apparatus 20. The communication modules may comprise a wireless or a wired interface module(s) or both. The wireless interface may comprise such as a WLAN, Bluetooth, infrared (IR), radio frequency identification (RF ID), GSM/GPRS, CDMA, WCDMA, LTE (Long Term Evolution) or 5G radio module. The wired interface may comprise such as Ethernet or universal serial bus (USB), for example. The communication interface 25 may support one or more different communication technologies. The apparatus 20 may additionally or alternatively comprise more than one of the communication interfaces 25. The communication interface 25 may provide the machine-machine interface of various disclosed embodiments.

A skilled person appreciates that in addition to the elements shown in FIG. 2, the apparatus 20 may comprise other elements, such as displays, as well as additional circuitry such as memory chips, application-specific integrated circuits (ASIC), other processing circuitry for specific purposes and the like. Further, it is noted that only one apparatus is shown in FIG. 2, but the embodiments of present disclosure may equally be implemented in a cluster of shown apparatuses.

FIGS. 3 and 4 show flow diagrams illustrating example methods according to certain embodiments. The methods may be implemented in the control unit 111 or the data handling environment 121 of FIG. 1 and/or in the apparatus 20 of FIG. 2. The methods are implemented in a computer and do not require human interaction unless otherwise expressly stated. It is to be noted that the methods may however provide output that may be further processed by humans and/or the methods may require user input to start. Different phases shown in the flow diagrams may be combined with each other and the order of phases may be changed except where otherwise explicitly defined. Furthermore, it is to be noted that performing all phases of the flow diagram is not mandatory.

The method of FIG. 3 illustrates actions performed in a control unit of drop test equipment and comprises the following phases:

301: A machine-machine interface is provided. A test script is obtained over the machine-machine interface. A single test script is referred to, but clearly it is possible to obtain a plurality of test scripts sequentially or in parallel. The test script defines a plurality of test settings for drop testing of a device-under-test, DUT.

The test settings may define one or more of the following: number of drop repetitions, position of the DUT, orientation of the DUT, velocity of the DUT, drop height, environmental parameters, such as temperature and humidity, drop base material. Further, the test script may define what kind of test results should be obtained and how they should be reported.

The test script may be obtained from an external data handling environment or from some other source providing predefined test scripts.

302: The drop test equipment is controlled to perform drop testing of the DUT according to the test settings of the test script.

This phase may involve interacting with a human-machine interface to guide the operator of the drop test equipment to perform the drop testing. For example, instructions and/or questions may be displayed on a display. The instructions may concern individual settings defined in the test script. The instructions may be given sequentially and/or a confirmation of the test settings having been configured may be requested. In this way, the risk of human errors in test settings may be reduced, as the operator of the drop test equipment does not need to manually input the test settings to the drop test equipment.

As a further practical example, a mounting head of the drop test equipment may include position detector configured to detect position of the mounting head and/or position of a DUT mounted on the mounting head. If the output of the position detector does not conform with the test settings of the test script, feedback may be provided about the discrepancy and the operator of the drop test equipment may be provided with instructions to correct the discrepancy.

In an example embodiment, this phase involves automatically configuring parameters of the drop test equipment according to test settings of the test script. Automatic configuration of the test settings may involve requesting a confirmation of the automatically configured settings from the operator, but this is not mandatory. In this way, the risk of human errors in test settings may be reduced as at least some settings are automatically configured. For example, velocity of the DUT, drop height, environmental parameters, such as temperature and humidity, or the like may be automatically configured.

303: Test results are collected.

This phase may involve interacting with a human-machine interface to receive test results from the operator of the drop test equipment. Collection of the test results may include collecting or requesting intermediate results during the drop testing and/or final test results in the end of drop testing sequence.

Additionally or alternatively, at least some test results may be automatically detected. This may be performed e.g. through imaging devices (e.g. still camera, video camera, or high-speed camera) and/or suitable sensors.

The test results may include numerical values, written statements and/or images of the DUT.

Additionally or alternatively, the test results may include test statistics collected before or during drop testing of the DUT. The test statistics may include one or more of the following: total test time, time spent on different phases of the drop testing, number of drop repetitions, position of the DUT, velocity of the DUT, drop height, environmental parameters, such as temperature and humidity. At least some of these may be automatically collected from the drop test equipment.

In an example embodiment, the human-machine interface may be configured to provide the operator of the drop test equipment a selection of predefined test results to choose from. The operator may choose the test result e.g. from the following options: no scratches or cracks on the cover, visible scratches on the backside/frontside of the cover, visible scratches on the sides of the cover, visible scratches on the bottom/upper part of the cover, cracks on the backside/frontside of the cover, cracks on the sides of the cover, cracks on the bottom/upper part of the cover. This is clearly only one example and other options are equally possible. In this way, it can be ensured that the test results provided by different operators are comparable with each other.

The collection of the test results may simplify documenting and reporting tasks of the operator.

304: The collected test results are provided to a test report.

305: Optionally, a full test report may be compiled in the control unit based on the collected test results. Alternatively only raw data may be collected and the full test report compiled in another process and/or another device.

306: Optionally, the test results and/or the test report may be submitted over the machine-machine interface to a predefined destination or to a predefined (network) address. The predefined destination may be the source of the test script, e.g. the external data handling environment where the test script was originally defined, but different destination may be used, too. The test results and/or the test report may be submitted to a predefined email address or to a predefined data storage or to some other predefined address, for example. In this way, the test report may be easily distributed to different destinations including e.g. a design department developing the DUT or subscriber of the drop testing of the DUT.

The method of FIG. 4 illustrates actions performed in a data handling environment or the like. The method comprises the following phases:

401: A human-machine interface is provided. The human-machine interface allows a supervisor to define a test script comprising a plurality of test settings for drop testing of a device-under-test, DUT.

The test settings may define one or more of the following: number of drop repetitions, position of the DUT, velocity of the DUT, drop height, environmental parameters, such as temperature and humidity, drop base material. Further, the test script may define what kind of test results should be obtained and how they should be reported.

The test script defined by the supervisor may be stored in a database or some other data storage for later access. In this way, the test script can be repeatedly accessed without needing to recreate the test script every time.

Further, the human-machine interface may allow the supervisor to use previous test scripts as a template for new test scripts. In this way, efficiency of test script creation may be improved. Also risk of human errors may be reduced, especially if proofed previous test scripts are used as templates.

402: A machine-machine interface is provided. The test script is transferred over a machine-machine interface to a control unit of a drop test equipment for being executed in the control unit to control the drop test equipment to perform drop testing of the DUT according to the test settings of the test script.

It is to be noted that the test script may be transferred for execution by the control unit right after the test script has been defined. Alternatively, the test script may be transferred later on. Additionally or alternatively, the test script may be transferred to a plurality of different drop test sites (i.e. to control units of a plurality of different drop test equipment).

403: Test results for the plurality of test settings are collected over the machine-machine interface. The collected test results may be in the form of raw data or in the form of a test report.

The test results may include numerical values, written statements and/or images of the DUT.

Additionally or alternatively, the test results may include test statistics collected before or during drop testing of the DUT. The test statistics may include one or more of the following: total test time, time spent on different phases of the drop testing, number of drop repetitions, position of the DUT, orientation of the DUT, velocity of the DUT, drop height, environmental parameters, such as temperature and humidity. At least some of these may be automatically collected from the drop test equipment.

404: Optionally, a full test report may be compiled in the data handling environment based on the collected test results.

The method of FIG. 4 may be performed in a physically different place compared to the drop test site where the drop test equipment is located. In this way, it is possible to remotely to control the drop testing from different location and possibly even from different country. Further, different drop test sites may be controlled from one central location. In this way resources may be saved.

Nevertheless, it is to be noted that in an alternative implementation, the actions discussed in connection with FIGS. 3 and 4 may be performed in the same device or the same logical entity.

In a further embodiment, settings of the drop test equipment are being monitored before or during drop testing of the DUT, and feedback is provided, if the settings of the drop test equipment do not conform with the test settings of the respective test script. The feedback may be for example an alarm and/or instructions to adjust the test settings and/or instructions to redo the respective drop test. In this way, the risk of human errors in test settings may be reduced as at least some settings are automatically double checked.

The compilation of the full test report may involve inclusion of additional data to the test results. For example, images of the DUT and/or information about the drop test context may be included. The context information may comprise for example information about physical test location, identification of the operator of the drop test equipment or the like.

The test scripts of various embodiments of present disclosure may be used for controlled calibration of the drop test equipment. As an example, the control unit of the drop test equipment may be configured to obtain and run a calibration test script over predefined intervals. The calibration test script defines tests for a known test piece. The expected test results are known and accuracy of the drop test equipment may be evaluated based on comparing test results of a performed calibration test to the expected results. Based on the comparison, necessary adjustments, if any, may be implemented in the drop test equipment.

Without a limiting effect, a technical advantage of one or more of the example embodiments disclosed herein is improved drop testing with robust test repeatability.

Another technical advantage of one or more of the example embodiments disclosed herein is ability to monitor and control that the drop tests are performed as intended. Further, risk of human errors may be reduced and efficiency of the drop testing may be improved.

If desired, the different functions discussed herein may be performed in a different order and/or concurrently with each other. Furthermore, if desired, one or more of the before-described functions may be optional or may be combined.

Various embodiments have been presented. It should be appreciated that in this document, words comprise, include and contain are each used as open-ended expressions with no intended exclusivity.

The foregoing description has provided by way of non-limiting examples of particular implementations and embodiments a full and informative description of the best mode presently contemplated by the inventors for carrying out embodiments of present disclosure. It is however clear to a person skilled in the art that present disclosure is not restricted to details of the embodiments presented in the foregoing, but that it can be implemented in other embodiments using equivalent means or in different combinations of embodiments without deviating from the characteristics of the present disclosure.

Furthermore, some of the features of the afore-disclosed example embodiments may be used to advantage without the corresponding use of other features. As such, the foregoing description shall be considered as merely illustrative of the principles of the present disclosure, and not in limitation thereof. Hence, the scope of the present disclosure is only restricted by the appended patent claims.

1. A computer implemented method in a control unit of drop test equipment for controlling the drop test equipment, the method comprising
obtaining, over a machine-machine interface, predefined test scripts from a data handling environment, each predefined test script comprising a plurality of test settings for drop testing of a device-under-test, DUT;
controlling the drop test equipment to perform drop testing of the DUT according to the test settings defined in the test scripts;
collecting test results for the plurality of test settings; and
providing the collected test results to a test report; and
providing the test results or the test report, over the machine-machine interface, to a predefined destination or address.

2. The method of claim 1, further comprising
monitoring settings of the drop test equipment before or during drop testing of the DUT; and
providing feedback if the settings of the drop test equipment do not conform with the test settings of the respective test script.

3. The method of claim 1, wherein the test settings define one or more of the following: number of drop repetitions, position of the DUT, orientation of the DUT, velocity of the DUT, drop height, temperature, humidity, drop base material.

4. The method of claim 1, wherein controlling the drop test equipment to perform the drop testing comprises interacting with a human-machine interface to guide an operator of the drop test equipment to perform the drop testing.

5. The method of claim 1, wherein controlling the drop test equipment to perform the drop testing comprises automatically configuring parameters of the drop test equipment according to test settings of the test script.

6. The method of claim 1, wherein collecting the test results comprises interacting with a human-machine interface to receive test results from the operator of the drop test equipment.

7. The method of claim 1, wherein collecting the test results comprises automatically detecting test results.

8. The method of claim 1, wherein collecting the test results further comprises collecting test statistics during drop testing of the DUT, wherein the test statistics include one or more of the following: total test time, time spent on different phases of the drop testing, number of drop repetitions, position of the DUT, orientation of the DUT, velocity of the DUT, drop height, temperature, humidity.

9. The method of claim 1, further comprising compiling (305, 404) the test report based on the collected test results.

10. The method of claim 1, wherein the test scripts are used for calibration of the drop test equipment.

11. The method of claim 1, wherein collecting the test results comprises obtaining position of the DUT or position of a mounting head in which the DUT is mounted, and comparing the obtained position to the test settings.

12. The method of claim 1, wherein data transfer through the machine-machine interface is secured with an encryption protocol.

13. The method of claim 1, further comprising
providing, in the data handling environment, a human-machine interface allowing a supervisor to define the test scripts comprising plurality of test settings for drop testing of a device-under-test, DUT;
transferring the test scripts, over the machine-machine interface, from the data handling environment to the control unit of the drop test equipment to control the drop test equipment to perform drop testing of the DUT according to the test settings defined in the test scripts; and
collecting, to the data handling environment, over the machine-machine interface, test results for the plurality of test settings.

14. The method of claim 13, wherein at least one test script is allowed to be transferred from the data handling environment to control units of a plurality of different drop test equipment of different drop test sites.

15. An apparatus comprising
a machine-machine interface,
processing intelligence configured to control drop test equipment;
wherein the processing intelligence is configured
to obtain, over the machine-machine interface, predefined test scripts from a data handling environment, each predefined test script comprising a plurality of test settings for drop testing of a device-under-test, DUT;
to control the drop test equipment to perform testing of the DUT according to the test settings defined in the test scripts;
to control the drop test equipment to perform drop testing of the DUT according to the test settings defined in the test scripts;
to collect test results for the plurality of test settings; and
to provide the collected test results to a test report; and
to provide the test results or the test report, over the machine-machine interface, to a predefined destination or address

16. The apparatus of claim 15, further comprising
a human-machine interface, wherein
the processing intelligence is configured to implement through the human-machine interface at least one of: controlling the drop test equipment and collecting the test results.

17. The apparatus of claim 15, wherein the memory and the computer program code are further configured to, with the processor, cause the apparatus to obtain position of the DUT or position of a mounting head in which the DUT is mounted, and to compare the obtained position to the test settings.

18. The apparatus of claim 15, wherein the memory and the computer program code are further configured to, with the processor, cause the apparatus to collect test statistics during drop testing of the DUT in addition to collecting the test results.

19. The apparatus of claim 15, wherein the test results comprise numerical values, written statements and images of the DUT.

20. A non-transitory memory medium comprising computer executable program code which when executed by a processor causes an apparatus to perform
obtaining, over a machine-machine interface, predefined test scripts from a data handling environment, each predefined test script comprising a plurality of test settings for drop testing of a device-under-test, DUT;
controlling the drop test equipment to perform drop testing of the DUT according to the test settings defined in the test scripts;
collecting test results for the plurality of test settings; and
providing the collected test results to a test report; and
providing the test results or the test report, over the machine-machine interface, to a predefined destination or address.
